(19) United States
(12) Patent Application Publication
(10) Pub. No.: US 2026/0005057 A1
(43) Pub. Date: Jan. 1, 2026

(54) SEMICONDUCTOR WAFER PROCESSING APPARATUS

(71) Applicant: Samsung Electronics Co., Ltd., Suwon-si (KR)

(72) Inventors: Yonjoo Kang, Suwon-si (KR); Byoungmin Yun, Suwon-si (KR); Dasom Lee, Suwon-si (KR); Minsung Kim, Suwon-si (KR); Sangyeon Oh, Suwon-si (KR); Hyogyun Jeong, Suwon-si (KR); Minsung Han, Suwon-si (KR)

(21) Appl. No.: 19/018,089

(22) Filed: Jan. 13, 2025

(30) Foreign Application Priority Data
Jun. 27, 2024 (KR) 10-2024-0084839

(51) Int. Cl. H01L 21/683

(52) U.S. Cl. CPC H01L 21/6833

(57) ABSTRACT

A semiconductor wafer processing apparatus includes an electrostatic chuck having an electrostatic chuck body with an upper surface configured to support a semiconductor wafer, a plurality of RF electrodes embedded in an inner upper portion of the electrostatic chuck body of the electrostatic chuck, each of the RF electrodes configured to receive electrical power for generating a chucking force with a back side of the semiconductor wafer supported by the upper surface of the electrostatic chuck, a chucking sensor electrode embedded in the electrostatic chuck body and disposed between the upper surface of the electrostatic chuck body and the plurality of RF electrodes, and the chucking sensor electrode configured to detect a flow of current or voltage between the back side of the semiconductor wafer and the plurality of RF electrodes of the electrostatic chuck body point, and a heater disposed below the plurality of RF electrodes.

### CROSS-REFERENCE TO RELATED APPLICATION(S)

This application claims benefit of priority to Korean Patent Application No. 10-2024-0084839 filed on Jun. 27, 2024, in the Korean Intellectual Property Office, the disclosure of which is incorporated herein by reference in its entirety.

### BACKGROUND

The present inventive concept relates to a semiconductor wafer processing apparatus that enables a semiconductor wafer to be chucked on an electrostatic chuck so that warpage does not occur in the semiconductor wafer.

An electrostatic clamp or electrostatic chuck (ESC) (hereinafter referred to as an electrostatic chuck) is generally used to chuck a semiconductor wafer only by force of electrostatic electricity during a plasma-based or vacuum-based semiconductor process, such as an etching, chemical vapor deposition (CVD), and ion implantation process.

The electrostatic chuck includes a dielectric layer disposed on a conductive electrode, and a semiconductor wafer is disposed on a dielectric surface of the electrostatic chuck. During the semiconductor process, a chucking voltage is applied between the semiconductor wafer and the conductive electrode, and the semiconductor wafer is chucked on a surface of the electrostatic chuck by electrostatic force.

During a chemical vapor deposition (CVD) process of depositing a film on a semiconductor wafer at high temperature, warpage may occur in the chucked semiconductor wafer.

A higher voltage may be applied to address a warpage problem of the semiconductor wafer occurring on the electrostatic chuck and a stronger chucking force may occur on the wafer on the electrostatic chuck. The stronger chucking force may result in a phenomenon of back side scratches or film peeling of the semiconductor wafer may occur.

In order to reduce the occurrence of warpage of semiconductor wafers, technologies have been developed to respond by increasing the emboss density of the electrostatic chuck surface or to control the chucking force by region.

However, due to process variables, such as differences in temperature, pressure, plasma gas, and the number of mold stacks of the process, different semiconductor wafer warpage shapes occur and it is not easy to provide the optimal chucking force accordingly.

### SUMMARY

An aspect of the present inventive concept is to provide a semiconductor wafer processing apparatus including an electrostatic chuck capable of rapidly sensing warpage of a semiconductor wafer seated on an electrostatic chuck during a semiconductor process performed at high temperature.

Another aspect of the present inventive concept is to provide a semiconductor wafer processing apparatus for rapidly sensing warpage of a semiconductor wafer on an electrostatic chuck and then controlling chucking force at a point at which warpage has occurred to flatten the semiconductor wafer.

According to an aspect of the present inventive concept, a semiconductor wafer processing apparatus includes: an electrostatic chuck having an electrostatic chuck body with an upper surface configured to support a semiconductor wafer configured to support; a plurality of RF electrodes embedded in an inner, upper portion of the electrostatic chuck body, each of the RF electrodes configured to receive electrical power for generating chucking force with a back side of the semiconductor wafer supported by the upper surface of the electrostatic chuck; a chucking sensor electrode embedded in the electrostatic chuck body and disposed between upper surface of the electrostatic chuck body and the plurality of RF electrodes, and the chucking sensor electrode configured to detect a change in flow of current or voltage between the back side of the semiconductor wafer supported by the upper surface of the electrostatic chuck and the plurality of RF electrodes; and a heater disposed below the plurality of RF electrodes and configured to heat the electrostatic chuck body.

According to an aspect of the present inventive concept, a semiconductor wafer processing apparatus includes: a process chamber having a shower head in an upper portion thereof; an electrostatic chuck located to face the shower head inside the process chamber; and a shaft supporting the electrostatic chuck, wherein the electrostatic chuck has an upper surface, a cylindrical sidewall, and a lower surface and includes a disk-shaped electrostatic chuck body formed of a ceramic material, a semiconductor wafer seated on an upper surface of the electrostatic chuck body, and the electrostatic chuck body includes: a plurality of RF electrodes embedded in an inner upper portion of the electrostatic chuck body; a chucking sensor electrode embedded in the electrostatic chuck body and disposed between the semiconductor wafer and the plurality of RF electrodes; and a heater disposed below the plurality of RF electrodes.

According to an aspect of the present inventive concept, a semiconductor wafer processing apparatus that senses whether a semiconductor wafer is chucked on an electrostatic chuck and adjusts a voltage to correspond to a warpage of the semiconductor wafer, includes: a process chamber; and an electrostatic chuck arranged in an inner space of the process chamber, wherein the electrostatic chuck includes an electrostatic chuck body having an upper surface, a cylindrical sidewall, and a lower surface, a semiconductor wafer is mounted on the upper surface of the electrostatic chuck body, and the electrostatic chuck body includes: a plurality of RF electrodes embedded in an inner upper portion of the electrostatic chuck body; a chucking sensor electrode embedded in the electrostatic chuck body so as to be located between the semiconductor wafer and the plurality of RF electrodes; and a heater embedded below the plurality of RF electrodes.

### BRIEF DESCRIPTION OF DRAWINGS

The previously identified aspects and other aspects, features, and advantages of the present inventive concept will be more clearly understood from the following detailed description, taken in conjunction with the accompanying drawings, in which:

FIG. 1 is a schematic cross-sectional view of a semiconductor wafer processing apparatus according to an example embodiment of the present inventive concept;

FIG. 2 is a schematic cross-sectional view of an electrostatic chuck including a chucking sensor electrode according to an example embodiment of FIG. 1;

FIG. 3 is an enlarged view of region A of FIG. 2;

FIG. 4 is a plan view schematically illustrating a first example embodiment of an arrangement of chucking sensor electrodes;

FIG. 5 is a plan view schematically illustrating a second example embodiment of an arrangement of chucking sensor electrodes;

FIG. 6 is a plan view schematically illustrating a third example embodiment of an arrangement of chucking sensor electrodes;

FIG. 7 is a plan view schematically illustrating a fourth example embodiment of an arrangement of chucking sensor electrodes;

FIG. 8 is a schematic diagram illustrating voltage distribution when semiconductor wafer warpage occurs in a chucking sensor electrode;

FIG. 9 is a schematic diagram illustrating voltage distribution when semiconductor wafer warpage does not occur in a chucking sensor electrode; and

FIG. 10 is a schematic diagram illustrating an installation of a filter for voltage detection of a chucking sensor electrode.

Some of the drawings are included as schematic diagrams. The drawings are illustrated for illustrative purposes and should not be considered to be drawn to scale. In addition, the drawings as schematic diagrams are provided to aid understanding and may not include all aspects or information compared to realistic representations and may include exaggerated information.

### DETAILED DESCRIPTION

Hereinafter, example embodiments of the present inventive concept will be described with reference to the accompanying drawings.

The example embodiments of the present inventive concept may be modified into other forms and are provided so that this disclosure will be thorough and complete and will fully convey the scope of the invention to those of ordinary skill in the art. In the drawings, the shapes and dimensions of elements may be exaggerated for clarity, and like reference numerals denote like elements. Elements indicated by identical or similar reference numerals on the drawings indicate identical or similar elements. When a single element is described that is shown as a plurality of elements in the drawings, it will be understood that the description of the single element is application to the other elements of the plurality.

Hereinafter, it will be understood that an element is referred to as being “above (or under)” or “on (or below)” another, it may be on an upper surface (or a lower surface) of the other element and intervening elements may be present between the element and the other element on (or below) the element.

In the present inventive concept, it will be further understood that when an element is referred to as being “connected to,” “coupled to” or “joined to” another element, it may be directly connected or joined to the other element, or intervening elements May be present, or each element may be “connected to,” “coupled to” or “joined to” each other through another element. Also, as will be evident from the context, “connected to,” “coupled to” or “joined to” includes elements that are “electrically connected.”

As used herein, elements described as being “electrically connected” are configured such that an electrical signal can be transferred from one element to the other (although such electrical signal may be attenuated in strength as it is transferred and May be selectively transferred). Moreover, elements that are “directly electrically connected” form a common electrical node through electrical connections by one or more conductors, such as, for example, wires, pads, internal electrical lines, through vias, etc. As such, directly electrically connected elements do not include components electrically connected through active elements, such as transistors or diodes.

It may be understood that when an element is referred to with “first” and “second,” the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element May also be referred to as a first element. In addition, an element that is referenced with a particular ordinal number (e.g., “first”) in a particular claim may be described elsewhere with a different ordinal number (e.g., “second”) in the specification or another claim.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

The terms used in the present inventive concept are used to simply describe an example and are not intended to limit the present inventive concept. Singular terms include plural forms thereof, unless otherwise indicated.

Hereinafter, a semiconductor wafer processing apparatus having an electrostatic chuck equipped with a chucking sensor function will be described through some example embodiments of the present inventive concept.

The present inventive concept provides for performing a manufacturing process with reduced abnormalities by measuring a voltage, not capacitance, between a sensor chip of an electrostatic chuck (ESC) and a substrate in-situ in real time during a semiconductor process by the sensor chip. The voltage measurement can be used to determine whether a semiconductor wafer is accurately seated on the electrostatic chuck without warpage in real time from a change in the measured voltage distribution.

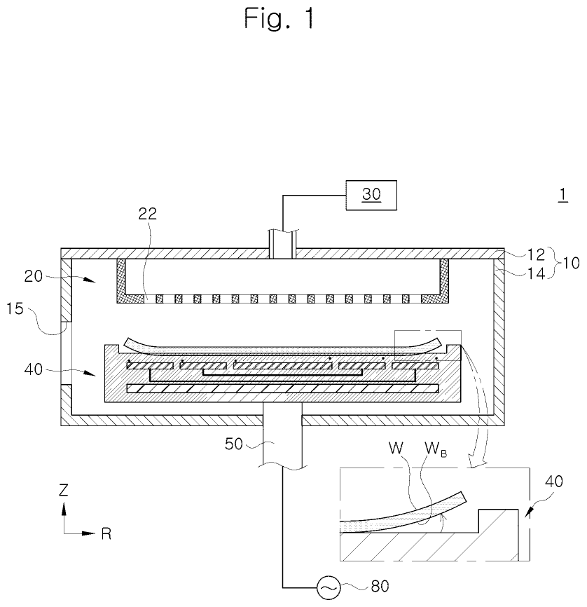

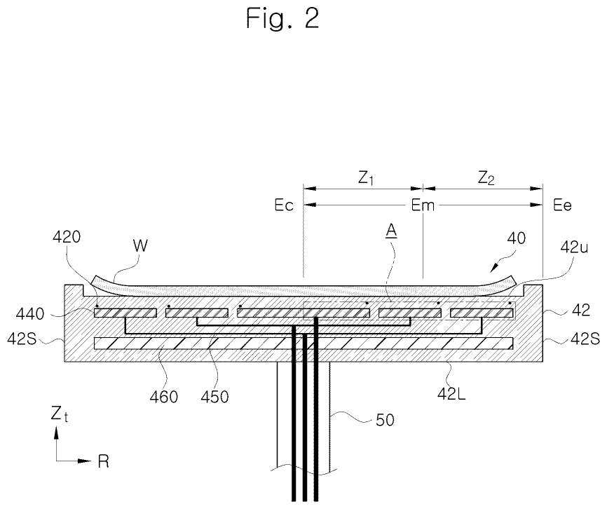

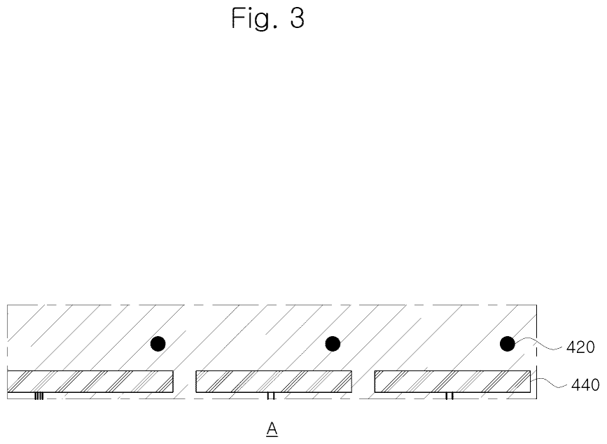

FIG. 1 is a schematic cross-sectional view of a semiconductor wafer processing apparatus according to an example embodiment of the present inventive concept, FIG. 2 is a cross-sectional view schematically illustrating an electrostatic chuck equipped with a chucking sensor electrode according to an example embodiment of FIG. 1, and FIG. 3 is an enlarged view of region A of FIG. 2.

A semiconductor wafer processing apparatus 1 according to an example embodiment of the present inventive concept includes a process chamber 10, an electrostatic chuck 40, and a shaft 50.

A semiconductor process performed in the semiconductor wafer processing apparatus 1 of the present example embodiment may include, for example, at least one of a deposition process, an etching process, or a cleaning process. During the deposition process, a film is deposited on a substrate, such as a semiconductor wafer W, at high temperature, using a process such as chemical vapor deposition (CVD), plasma enhanced chemical vapor deposition (PECVD), or hot wire chemical vapor deposition (HWCVD). The CVD and PECVD processes are performed by introducing process gases into the process chamber 10 with the semiconductor wafer W disposed inside. The process gases are diffused toward the semiconductor wafer W through a showerhead 20 disposed in an upper portion of the process chamber 10.

In the process chamber 10 a chamber upper end 12 (e.g., a chamber top) and a chamber lower end 14 (e.g., a chamber body) may be combined (e.g., joined) so that an internal space in which a semiconductor process is performed is formed.

The process chamber 10 may be formed of a metal material, such as aluminum (Al), and in an example embodiment, a wafer transfer port 15 through which the semiconductor wafer W is introduced or removed may be included on a chamber sidewall of the chamber lower end 14. The wafer transfer port 15 may be coupled to a transfer chamber and/or other chambers of another semiconductor wafer processing apparatus.

The process chamber 10 includes the electrostatic chuck 40 suitable for operation in a high temperature range, for example, from about 100° C. to about 700° C.

The electrostatic chuck 40 includes an electrostatic chuck body 42 having an upper surface 42U, a cylindrical sidewall 42S, and a lower surface 42L. The electrostatic chuck has a disk shape and may be formed of a ceramic material.

In order to clarify the description of each example embodiment, the directions are consistent for each of the figures. Referring to FIG. 1, a Zt direction, which illustrates an up-down direction of the process chamber 10, is defined as a thickness direction of the electrostatic chuck, and an R direction, which illustrates a horizontal direction of the process chamber 10, is defined as a radial direction of the electrostatic chuck having a disk shape.

The electrostatic chuck body 42 may include a plurality of RF electrodes 440, a chucking sensor electrode 420, and a heater 460.

The plurality of RF electrodes 440 may be embedded in an upper portion of the electrostatic chuck body 42 in the thickness direction. The electrostatic chuck 40 may generate a chucking force through an electrostatic force resulting from the application of a voltage to the RF electrodes. The chucking force holds the semiconductor wafer W on the upper surface 42U of the electrostatic chuck body 42.

The semiconductor wafer W may be seated on the upper surface 42U of the electrostatic chuck body 42, and the electrostatic chuck 40 may generate a Johnsen-Rahbek chucking force at high temperature exceeding about 450° C.

The electrostatic chuck body 42 may include a material having a volume resistivity that may generate the Johnsen-Rahbek chucking force. For example, the electrostatic chuck body 42 may be formed of a bulk type dielectric material, for example, aluminum nitride (AlN). For example, the volume resistivity of the electrostatic chuck body may be greater than 10¹³ ohm-cm.

The plurality of RF electrodes 440 may be connected to a power supply 80 that supplies a chucking voltage of about 0 volts to about 5000 volts. Each RF electrode 440 may have a terminal or a lead which may be connected to a RF line that provides an electrical connection to the power supply 80. The plurality of RF electrodes 440 may selectively be driven with a DC voltage supplied from the power supply 80.

When an appropriate voltage is applied to the plurality of RF electrodes 440, a chucking force is generated between the plurality of RF electrodes 440 and a back side Wb of the semiconductor wafer W on the upper surface 42U. Due to the chucking force, the semiconductor wafer W is seated and held on the upper surface 42U of the electrostatic chuck body 42 during the semiconductor process.

The semiconductor process of depositing various materials may be sensitive to temperature. In the semiconductor process, the electrostatic chuck 40 may act as a heat source for the semiconductor wafer W during the deposition process. As the semiconductor process is performed, a plurality of material layers may be formed on the semiconductor wafer W. The plurality of material layers may apply stress to the semiconductor wafer W, and this stress may cause warpage to occur in the semiconductor wafer W.

The electrostatic chuck 40 may offset the warpage and secure the semiconductor wafer W so that it remains flat on the upper surface 42U of the electrostatic chuck body 42. When the semiconductor wafer W maintains uniform contact with the upper surface 42U of the electrostatic chuck body 42 (e.g., remains flat), the semiconductor wafer W may be heated more evenly.

During the semiconductor process, in addition to warpage that may occur in the semiconductor wafer W, the semiconductor wafer W may expand or drift on the upper surface 42U of the electrostatic chuck body 42 due to various causes, such as high temperature, high pressure, and plasma gas within the process chamber 10 if the semiconductor wafer W is not secured.

When the semiconductor wafer W expands or drifts on the upper surface 42U of the electrostatic chuck body 42, the back side Wb of the semiconductor wafer W may be scratched or imprinted due to the embossing of the upper surface 42U of the electrostatic chuck body 42, resulting in separation of a deposited membrane material.

In order to prevent the occurrence of warpage, back side scratches, or imprinting of the semiconductor wafer W as described above, the semiconductor wafer W should be rapidly re-chucked on the upper surface 42U of the electrostatic chuck body 42 through adjusting the chucking force by applying an updated optimum voltage to the electrostatic chuck 40.

In the present example embodiment, the semiconductor wafer W may be rapidly re-chucked on the upper surface 42U of the electrostatic chuck body 42 and flattened (e.g., secured to the upper surface 42U) by rapidly detecting a point (e.g., a location in the semiconductor wafer W) at which warpage occurs on the semiconductor wafer W and adjusting a chucking voltage applied to one or more of the plurality of RF electrodes 440 corresponding to the point at which the warpage occurs.

After the semiconductor wafer W is re-chucked and flattened again on the upper surface 42U of the electrostatic chuck body 42, a lower chucking voltage may be applied to maintain the chucking force. The lower chucking voltage may prevent an excessive chucking force by one or more RF electrode 400 of the plurality of RF electrodes 440 corresponding to the point at which warpage occurs.

The control operation of the plurality of RF electrodes 440 on the semiconductor wafer W in which warpage occurs may improve deposition uniformity, overlay error, and chamber impedance of the semiconductor wafer W. In addition, the plurality of RF electrodes 440 may be used to minimize deposition on the back side Wb of the semiconductor wafer W and control warpage of the semiconductor wafer W.

To sense when the semiconductor wafer W is not in contact with the upper surface 42U of the electrostatic chuck body 42, such as when warpage occurs in the semiconductor wafer W, a chucking sensor electrode 420 is embedded in the electrostatic chuck body 42 and located between the semiconductor wafer W and the plurality of RF electrodes 440 in the thickness direction Z. The chucking sensor electrode may sense when a portion of the semiconductor wafer W is not in contact with the upper surface 42U such as when warpage or poor contact occurs. The chucking sensor electrode 420 may sense contact of the semiconductor wafer W at a single point of the chucking sensor electrode 420 such as at the end of the chucking sensor electrode 420 or as an average along the length of the chucking sensor electrode 420. For example, a chucking sensor electrode 420 that is concentric with the upper surface 42U may sense the average contact of the semiconductor wafer W in a concentric ring of the semiconductor wafer W.

The heater 460 may be embedded below the plurality of RF electrodes 440 of the electrostatic chuck body 42 in the thickness direction. The heater 460 may also be coupled to a power supply unit, such as the power supply unit 80 with the plurality of RF electrodes 440. The power supply unit supplies the heater 460 with power and may help control the temperature of the electrostatic chuck 40. For example, the heater may heat the electrostatic chuck 40.

The chucking sensor electrode 420 detects a change in a current or voltage flow between the back side Wb of the semiconductor wafer W and the plurality of RF electrodes 440 at a radial location of the electrostatic chuck body 42. For example, the chucking sensor electrode 420 may be an electric field sensor configured to measure the electric field between at the location of the chucking sensor electrode 420 or may be a current sensor configured to measure a microcurrent flowing in a thickness direction of the electrostatic chuck body at the location of the chucking sensor electrode 420.

A gap between the upper surface 42U and the semiconductor wafer W where the electrostatic chuck 40 and the semiconductor wafer W do not contact is formed due to a difference in roughness Ra between the upper surface 42U of the electrostatic chuck body 42 and the surfaces of the semiconductor wafer W. Since a gap acts as a dielectric, an electrostatic force is generated at the location in which the gap is formed. The difference in the electrostatic force occurring at positions where contact occurs and positions where contact does not occur between the semiconductor wafer W and the upper surface 42U of the electrostatic chuck body 42 may result in relatively different current or voltage distributions in various regions of the semiconductor wafer W in the radial direction (R direction).

A first voltage distribution in may be present when the semiconductor wafer W is chucked in each region and a change in the first voltage distribution may indicate that the semiconductor wafer W is not chucked in at least one region. Using the change in the voltage distributions it is possible to determine whether the semiconductor wafer W is chucked at each point or in each region. For example, a chucking sensor electrode 420 at a point or a region will detect the change in the voltage distribution as a change in current or voltage at that chucking sensor electrode 420.

The disk-shaped electrostatic chuck body 42 may be logically divided into a plurality of zones which may be non-overlapping annular zones, and in an example embodiment, the center of the electrostatic chuck body 42 may be defined as Ec, the edge of the electrostatic chuck body 42 may be defined as Ee, and the radial center between the center Ec of the electrostatic chuck body 42 and the edge Ee of the electrostatic chuck body 42 may be defined as Em. In addition, in the electrostatic chuck body 42, a concentric zone (e.g., an annular zone) between Ec and Em may be defined as Z₁ and a concentric zone between Em and Ee may be defined as Z₂. The division of a plurality of zones in this manner is arbitrary, and the electrostatic chuck body 42 may be logically divided into more zones depending on a specific point or the arrangement of the plurality of RF electrodes 440.

Separate voltage supply lines 450 connected to the power supply 80 at one end and each independently connected to a respective RF electrode at the other end may independently apply different voltages to each of the RF electrodes 440 to rapidly change the electrostatic force to respond to a warpage phenomenon of the semiconductor wafer W.

The chucking sensor electrode 420 may be embedded in the electrostatic chuck body 42 between the semiconductor wafer W and the plurality of RF electrodes 440 in the thickness direction Z and may detect changes in the current or voltage flow between the back side of the semiconductor wafer W and the plurality of RF electrodes.

The chucking sensor electrode 420 may have a wire shape, and other shapes are possible provided that the chucking sensor electrode 420 detects a change in a microcurrent between the back side Wb of the semiconductor wafer W and the plurality of RF electrodes 440. For example, the chucking sensor electrode 420 may have an ultrafine wire shape, but the shape is not particularly limited.

The chucking sensor electrode 420, as a sensor with no specific shape, may be disposed above the plurality of RF electrodes 440 in the thickness direction Z within the electrostatic chuck body 42, which expands or contracts at high temperatures.

The chucking sensor electrode 420 may have a coefficient of thermal expansion similar to of the same as that of the heater 460 of the electrostatic chuck body 42, and a preferable range of the coefficient of thermal expansion is 4.0 to 9.0×10⁻⁶/° C. For example, the coefficient of thermal expansion of the chucking sensor electrode 420 may be within 95% to 105% of the coefficient of thermal expansion of the electrostatic chuck body 42.

In order to reduce stress caused by different coefficients of thermal expansion in the electrostatic chuck body 42 and to have uniform thermal conductivity, the material of the chucking sensor electrode 420 may be selected from at least one of tungsten W, tantalum (T), molybdenum (Mo), niobium (Nb), and Kovar alloys having a coefficient of thermal expansion similar to (e.g., within ±5%) that of the material of the electrostatic chuck body 42.

Hereinafter, the arrangement of the chucking sensor electrode 420 will be described in further detail.

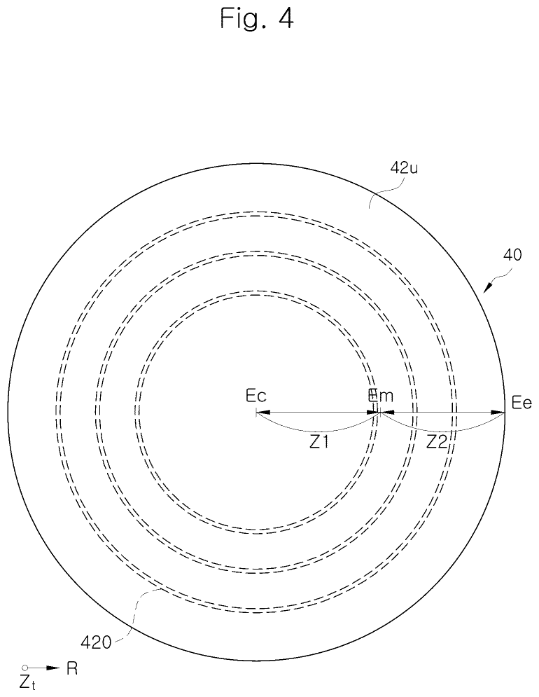

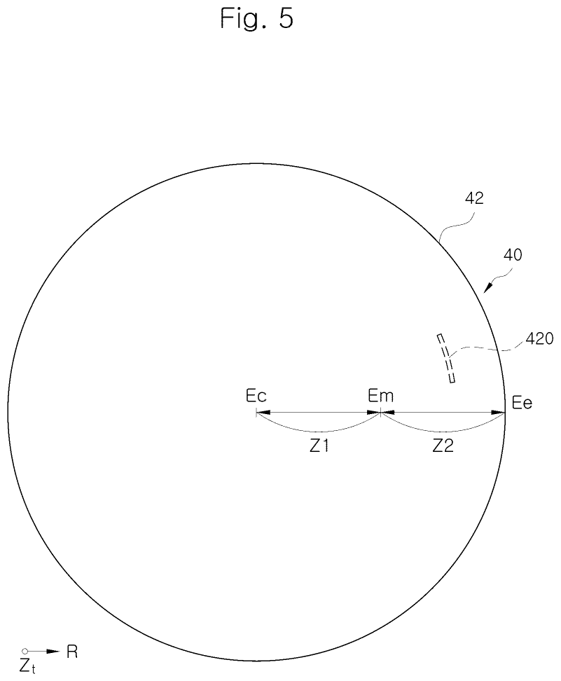

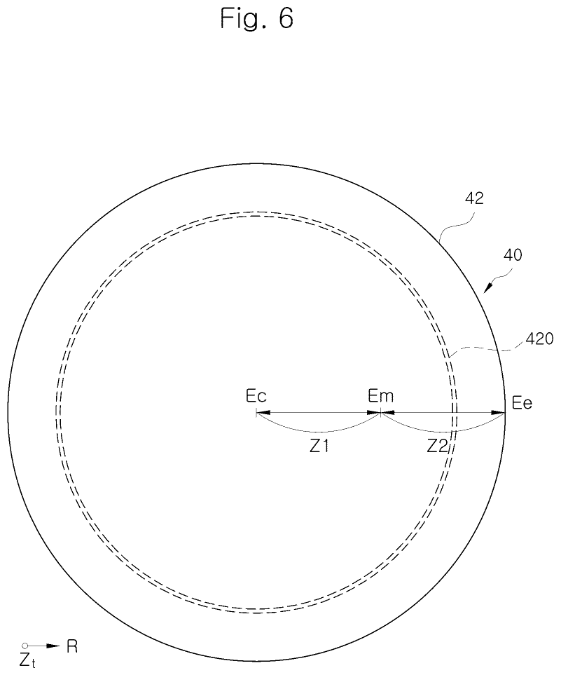

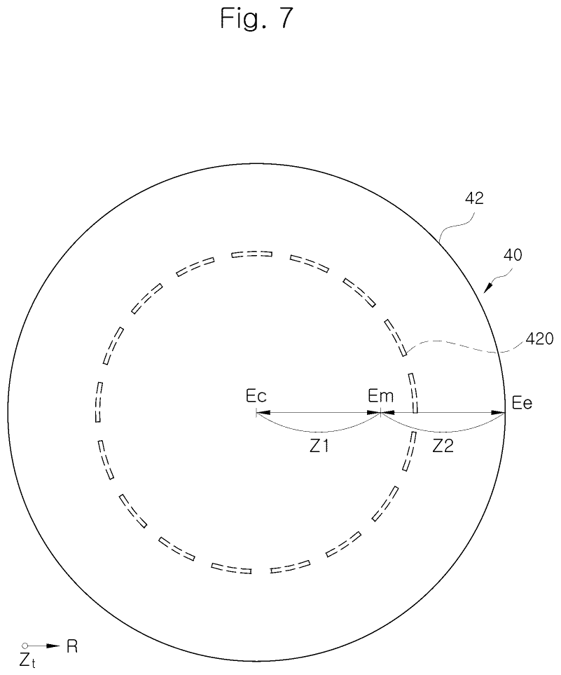

FIG. 4 is a plan view schematically illustrating a first example embodiment of an arrangement of chucking sensor electrodes, FIG. 5 is a plan view schematically illustrating a second example embodiment of an arrangement of chucking sensor electrodes, FIG. 6 is a plan view schematically illustrating a third example embodiment of an arrangement of chucking sensor electrodes, and FIG. 7 is a plan view schematically illustrating a fourth example embodiment of an arrangement of chucking sensor electrodes.

As shown in the example embodiment, the plurality of zones of the electrostatic chuck body 42 may be described as follows.

The disc-shaped electrostatic chuck body 42 may be logically divided into a plurality of zones, and in an example embodiment, the center of the electrostatic chuck body 42 may be defined as Ec, the edge of the electrostatic chuck body 42 may be defined as Ee, and the radial center between the center Ec of the electrostatic chuck body 42 and the edge Ee of the electrostatic chuck body 42 may be defined as Em. In addition, in the electrostatic chuck body 42, a concentric zone between Ec and Em may be defined as Z₁ and a concentric zone between Em and Ee may be defined as Z₂. The division of the zones in this manner is arbitrary, and the electrostatic chuck body 42 may be divided into more zones depending on a specific point or the arrangement of the plurality of RF electrodes 440.

The chucking sensor electrode 420 detects flow of a microcurrent between the back side Wb of the semiconductor wafer W and the plurality of RF electrodes 440 at a location of the electrostatic chuck body 42 in the radial direction R.

By detecting a change in a voltage distribution that may occur in each region of the electrostatic chuck 40 due to a change in the flow of microcurrent as described above, it is possible to determine whether the semiconductor wafer W is chucked. If chucking force of the semiconductor wafer W is weak and a different voltage distribution appears in one of the zones Z₁ and Z₂ of the electrostatic chuck body 42 or at a local point within each zone, the semiconductor wafer W may be re-chucked and flattened by providing a stronger voltage to the RF electrode in each of the zones Z₁ and Z₂ or at a local point within each zone in which a different voltage distribution appears.

There may be a chucking sensor electrode 420 arranged in at least one of the plurality of zones Z₁ and Z₂, and in the example embodiment of FIG. 4, there are three chucking sensor electrodes 420 with two chucking sensor electrodes 420 disposed Z₂ and a single chucking sensor electrode 420 disposed in zone Z₁. In the first zone Z₁, one ultrafine wire-shaped chucking sensor electrode 420 is disposed in a concentric shape, and in the second zone Z₂, two ultrafine wire-shaped chucking sensor electrodes 420 are arranged in a concentric shape.

The number of chucking sensor electrodes 420 may be arbitrarily determined according to the size of the semiconductor wafer W.

In the example embodiment of FIG. 5, when the electrostatic chuck body 42 is viewed in plan view, the chucking sensor electrode 420 is disposed in a local position in at least one of the plurality of zones Z₁ and Z₂.

For example, as illustrated in FIG. 5, the chucking sensor electrode 420 may be disposed at a local position in the second zone Z₂ near the outermost side in the radial direction. Accordingly, when an outer end portion of the semiconductor wafer W seated on the upper surface 42U of the electrostatic chuck body 42 warps upwardly (smile shape in a profile view) in the thickness direction, it is possible to sense whether the semiconductor wafer W is chucked.

In another example, the chucking sensor electrode 420 may be disposed at a local position in the first zone Z₁ near the center Ec in the radial direction. In this example, when warpage occurs (a crying shape in a profile view) upwardly in the thickness direction in the center of the semiconductor wafer W seated on the upper surface 42U of the electrostatic chuck body 42, it is possible to sense whether the semiconductor wafer W is chucked.

In the example embodiment of FIG. 6, when the electrostatic chuck body 42 is viewed in plan view, the chucking sensor electrode 420 may be arranged to have a concentric shape in at least one of the plurality of zones Z₁ and Z₂.

In another example, as in FIG. 6, a single wire-shaped chucking sensor electrode 420 may be disposed concentrically in the second zone Z₂ near the outermost side in the radial direction. According to example, when the outer end portion of the semiconductor wafer W seated on the upper surface 42U of the electrostatic chuck body 42 warps upwardly (smile shape) in the thickness direction, it is possible to sense whether the semiconductor wafer W is being chucked.

In another example, a single wire-shaped chucking sensor electrode 420 may be arranged continuously and concentrically in the first zone Z₁ near the center Ec. According to this example, when warpage occurs (crying shape) in the thickness direction upwardly in the center of the semiconductor wafer W seated on the upper surface 42U of the electrostatic chuck body 42, it is possible to sense whether the semiconductor wafer W is chucked.

In the example embodiment of FIG. 7, when the electrostatic chuck body 42 is viewed in plan view, the chucking sensor electrode 420 is disposed to have a discontinuous concentric shape in at least one of the plurality of zones Z₁ and Z₂.

For example, as illustrated in FIG. 7, the single wire-shaped chucking sensor electrode 420 may be arranged in a concentric shape discontinuously in the second zone Z₂ near the outermost side in the radial direction. According to this example, when warpage occurs (smile shape) in the thickness direction upwardly in the outer end portion of the semiconductor wafer W seated on the upper surface 42U of the electrostatic chuck body 42, it is possible to sense whether the semiconductor wafer W is chucked.

In another example, the single wire-shaped chucking sensor electrode 420 may be arranged in a concentric shape discontinuously in the first zone Z₁ near the innermost side in the radial direction. Accordingly, when warpage occurs (crying shape) in the thickness direction upwardly in the center of the semiconductor wafer W seated on the upper surface 42U of the electrostatic chuck body 42, it is possible to sense whether the semiconductor wafer W is chucked.

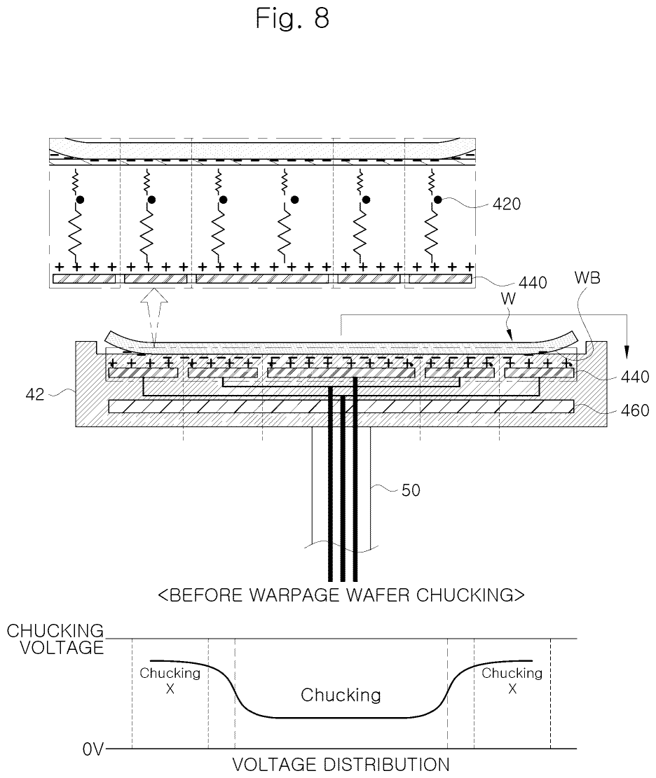

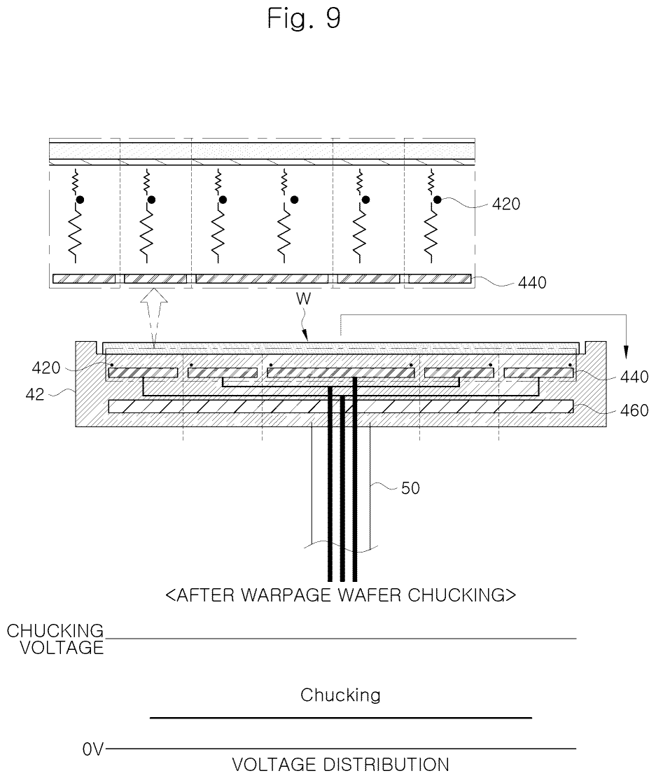

FIG. 8 is a schematic diagram illustrating a voltage distribution in the electrostatic chuck body 42 when semiconductor wafer warpage occurs, and FIG. 9 is a schematic diagram illustrating voltage distribution in the electrostatic chuck body 42 when semiconductor wafer warpage does not occur.

Referring to FIGS. 8 and 9, the operating principle of the chucking sensor electrode 420 will be described again.

After the semiconductor wafer W is disposed on an upper portion of the electrostatic chuck body 42, a semiconductor process is performed, and here, if a semiconductor process temperature rises, the volume resistivity of the material of the electrostatic chuck body 42 decreases and a Johnsen-Rahbek chucking force occurs between the plurality of RF electrodes 440 and the back side Wb of the semiconductor wafer W in a dielectric volume resistivity range of 10⁹˜10¹¹ (Ωcm).

With the Johnsen-Rahbek chucking force, the attraction acts as a counter electrode between the plurality of RF electrodes 440 and the back side Wb of the semiconductor wafer W. Thus, the voltage difference between the electrostatic chuck and the backside of the semiconductor wafer Wb is lower in locations where the semiconductor wafer W is chucked to the electrostatic chuck. In locations where the semiconductor wafer W becomes un-chucked, there is a loss in the Johsen-Rahbek chucking force and the counter electrode effect is reduced resulting in a higher voltage difference between the electrostatic chuck and the backside of the semiconductor wafer Wb.

When the semiconductor wafer W is chucked to the electrostatic chuck a leakage current flows between the electrostatic chuck body 42 and the semiconductor wafer W, and the chucking sensor electrode 420 may sense the current or voltage between the electrostatic chuck body 42 and the semiconductor wafer W.

Since the plurality of RF electrodes 440 are arranged with each RF electrode in a separate region of the electrostatic chuck body 42 and the chucking sensor electrode 420 is located between the plurality of RF electrodes 440 and the back side Wb of the semiconductor wafer W in the thickness direction, the difference in voltage distribution in each region of the electrostatic chuck body 42 may be measured based on a change in the flow of leakage current.

In FIG. 8, the voltage distribution indicates that the semiconductor wafer W is not chucked due to warpage occurring at the outermost end portion of the semiconductor wafer W, and thus, the voltage distribution increases in the outermost zone of the electrostatic chuck. When a non-chucked region is sensed (e.g., by a chucking sensor electrode 420), the semiconductor wafer W may be rapidly re-chucked as illustrated in FIG. 9 by adjusting the voltage of one of the plurality of RF electrodes 440 corresponding to the location of the non-chucked zone.

As illustrated in FIG. 9, after the semiconductor wafer W in which warpage had occurred is entirely chucked on the electrostatic chuck 40 and flattened, a leakage current flows from the back side Wb of the semiconductor wafer W to form a uniformly lower voltage than before chucking.

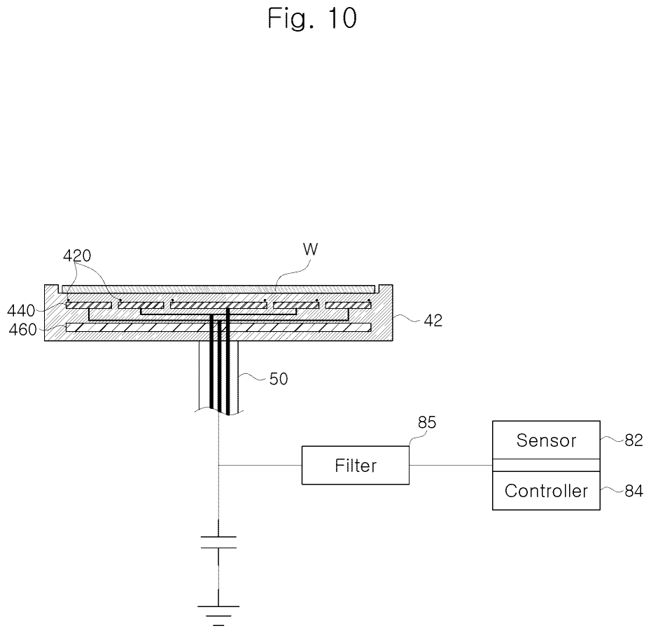

FIG. 10 is a schematic diagram illustrating an installation of a filter for voltage detection of a chucking sensor electrode.

Referring to FIG. 10, the semiconductor wafer W processing apparatus 1 of the present inventive concept includes the shaft 50 supporting the electrostatic chuck body 42. The shaft 50 may be a tube type having a line provided therein through which voltage is supplied to the RF electrodes.

The semiconductor wafer processing apparatus 1 of the present example embodiment may further include a filter 85 for reducing the noise of high frequency and AC voltage transmitted through the shaft 50. The filter 85 may be disposed inside or outside the shaft 50 and may be connected to the power supply 80.

A sensor 82 may receive a voltage signal from the chucking sensor electrode that passes through the filter 85 to rapidly sense when the semiconductor wafer W is in contact with the electrostatic chuck body 42, and a controller 84 may command the voltage supply to apply a higher voltage to the RF electrode 440 in a region in which warpage occurs.

Although not illustrated, the controller 84 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller (e.g., data connections to the sensor 82, data connection to the power supply 80 to control the voltage provided to the RF electrodes 440 and/or the heater 460), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include a power source that provides an appropriate alternating current (AC) or direct current (DC) to power one or more components of the controller, and a bus that allows communication among the various disclosed components of the controller.

The controller 84 may control the output of the power supply 80 for chucking the semiconductor wafer W to the upper surface 42U of the electrostatic chuck. For example, the controller 84 may receive a signal from the sensor 82 corresponding to an output of the chucking sensor electrode 420. There may be multiple chucking sensor electrodes 420 providing input to the sensor 82 or each chucking sensor electrode 420 may have a corresponding sensor 82. Each sensor 82 may correspond to a zone of the electrostatic chuck 40. Thus, the controller 84 may receive an input from a sensor 82 the indicates if the semiconductor wafer W is contacting the upper surface 42U of the electrostatic chuck body 42.

In response to the controller receiving an input from a sensor 82, the controller 84 may increase the voltage to one or more RF electrodes 440 associated with a zone the sensor 82 associated with. The increased voltage may increase the electrostatic force between the semiconductor wafer W and upper surface 42U and the semiconductor wafer W may thereby be re-chucked. In some embodiments, the controller 84 may increase the voltage until the sensor 82 indicates that the semiconductor wafer W is re-chucked. Once the semiconductor wafer W is re-chucked, the controller 84 may maintain the voltage or may reduce the voltage to a level at which the semiconductor wafer W remains chucked.

According to the semiconductor wafer processing apparatus of an example embodiment of the present inventive concept described above, by embedding a chucking sensor electrode between the plurality of RF electrodes of the present inventive concept and the upper surface of the electrostatic chuck body, warpage of the semiconductor wafer may be sensed from a change in leakage current depending on whether there is contact between the upper surface of the electrostatic chuck body and the back side of the semiconductor wafer. This enables the measurement of whether the semiconductor wafer W is chucked even without the need for secondary environments that may interfere with the semiconductor process, a separate AC voltage supply for semiconductor warpage W measurement, and the like, to measure warpage of the semiconductor wafer W.

In addition, in a high-temperature process, warpage of the semiconductor wafer may occur and the semiconductor wafer may drift due to the expansion of the electrostatic chuck body, and in this case, by rapidly sensing that and controlling to have an appropriate chucking force, the phenomenon in which the back side of the semiconductor wafer is scratched may be reduced and the reliability of the product, uniformity of the process, etc. may be guaranteed.

While example embodiments have been illustrated and described above, it will be apparent to those skilled in the art that modifications and variations could be made without departing from the scope of the present inventive concept as defined by the appended claims.

What is claimed is:

1. A semiconductor wafer processing apparatus comprising:
an electrostatic chuck having an electrostatic chuck body with an upper surface configured to support a semiconductor wafer;
a plurality of RF electrodes embedded in an inner, upper portion of the electrostatic chuck body, each of the RF electrodes configured to receive electrical power for generating a chucking force with a back side of the semiconductor wafer when supported by the upper surface of the electrostatic chuck;
a chucking sensor electrode embedded in the electrostatic chuck body and disposed between the upper surface of the electrostatic chuck body and the plurality of RF electrodes, the chucking sensor electrode configured to detect a change in flow of current or voltage between the back side of the semiconductor wafer when supported by the upper surface of the electrostatic chuck and the plurality of RF electrodes; and
a heater disposed below the plurality of RF electrodes and configured to heat the electrostatic chuck body.

2. The semiconductor wafer processing apparatus of claim 1, wherein the electrostatic chuck body includes a ceramic material, a coefficient of thermal expansion of the chucking sensor electrode is in a range of 4.0 to 9.0×10⁻⁶/° C., and a coefficient of thermal expansion of the electrostatic chuck body is 95% to 105% of the coefficient of thermal expansion of the chucking sensor electrode.

3. The semiconductor wafer processing apparatus of claim 1, wherein the chucking sensor electrode has a wire shape.

4. The semiconductor wafer processing apparatus of claim 1, wherein the chucking sensor electrode is configured to detect a flow of current or a voltage difference at a local position between the back side of the semiconductor wafer when supported by the upper surface of the electrostatic chuck and the plurality of RF electrodes of the electrostatic chuck body.

5. The semiconductor wafer processing apparatus of claim 4, wherein the electrostatic chuck body is divided into a plurality of non-overlapping annular zones, and the chucking sensor electrode is disposed in an outermost annular zone among the plurality of non-overlapping annular zones in a radial direction.

6. The semiconductor wafer processing apparatus of claim 5, wherein the chucking sensor electrode is one of a plurality of chucking sensor electrodes disposed concentrically in an outermost annular zone among the plurality of non-overlapping annular zones in the radial direction.

7. The semiconductor wafer processing apparatus of claim 4, wherein, in a plan view of the electrostatic chuck body, the chucking sensor electrode has a concentric shape.

8. The semiconductor wafer processing apparatus of claim 4, wherein the electrostatic chuck body is divided into a plurality of non-overlapping annular zones, the chucking sensor electrode is one of a plurality of chucking sensor electrodes and in a plan view of the electrostatic chuck body, the plurality of the chucking sensor electrodes are disposed in a concentric shape in one of the plurality of non-overlapping annular zones.

9. The semiconductor wafer processing apparatus of claim 1, further comprising:
a shaft connected to the electrostatic chuck body; and
a filter configured to reduce noise of high-frequency voltage transmitted through the shaft.

10. A semiconductor wafer processing apparatus comprising:
a process chamber having a showerhead in an upper portion thereof;
an electrostatic chuck located to face the showerhead inside the process chamber; and
a shaft configured to elevate the electrostatic chuck,
wherein the electrostatic chuck has an upper surface configured to seat a semiconductor wafer, a cylindrical sidewall, and a lower surface and includes an electrostatic chuck body formed of a ceramic material, and
the electrostatic chuck body includes:
a plurality of RF electrodes embedded in an inner, upper portion of the electrostatic chuck body;
a chucking sensor electrode embedded in the electrostatic chuck body and disposed between the semiconductor wafer and the plurality of RF electrodes; and
a heater disposed below the plurality of RF electrodes.

11. The semiconductor wafer processing apparatus of claim 10, wherein the chucking sensor electrode has a first coefficient of thermal expansion in a range of 4.0 to 9.0×10⁻⁶/° C. and the electrostatic chuck body has a second coefficient of thermal expansion that is within 5% of the first coefficient of thermal expansion.

12. The semiconductor wafer processing apparatus of claim 10, wherein the chucking sensor electrode includes at least one of tungsten W, tantalum (T), molybdenum (Mo), niobium (Nb), or a Kovar alloy.

13. The semiconductor wafer processing apparatus of claim 10, wherein the chucking sensor electrode has a wire shape.

14. The semiconductor wafer processing apparatus of claim 10, wherein the electrostatic chuck body is divided into a plurality of non-overlapping annular zones, and the chucking sensor electrode is disposed in one of the plurality of non-overlapping annular zones.

15. The semiconductor wafer processing apparatus of claim 14, wherein, in a plan view of the electrostatic chuck body, the chucking sensor electrode is disposed at a local position in one zone among the plurality of non-overlapping annular zones.

16. The semiconductor wafer processing apparatus of claim 14, wherein, in a plan view of the electrostatic chuck body the chucking sensor electrode is disposed concentrically in an outermost annular zone among the plurality of non-overlapping annular zones in a radial direction.

17. The semiconductor wafer processing apparatus of claim 14, wherein, in a plan view of the electrostatic chuck body the chucking sensor electrode has a concentric shape in one of the plurality of non-overlapping annular zones.

18. The semiconductor wafer processing apparatus of claim 14, wherein, the chucking sensor electrode is one of a plurality of chucking sensor electrodes is disposed concentrically in at least one of the plurality of non-overlapping annular zones.

19. The semiconductor wafer processing apparatus of claim 10, further comprising a filter reducing noise of a high frequency voltage transmitted through the shaft.

20. A semiconductor wafer processing apparatus that senses whether a semiconductor wafer is chucked on an electrostatic chuck and adjusts a voltage to respond to warpage of the semiconductor wafer, the semiconductor wafer processing apparatus comprising:
a process chamber; and
an electrostatic chuck arranged in an inner space of the process chamber,
wherein the electrostatic chuck includes an electrostatic chuck body having an upper surface, a cylindrical sidewall, and a lower surface,
wherein the electrostatic chuck is configured to seat a semiconductor wafer on the upper surface of the electrostatic chuck body, and
the electrostatic chuck body includes:
a plurality of RF electrodes embedded in an inner upper portion of the electrostatic chuck body;
a chucking sensor electrode embedded in the electrostatic chuck body and disposed between the semiconductor wafer when seated on the upper surface of the electrostatic chuck body and the plurality of RF electrodes; and
a heater disposed below the plurality of RF electrodes.
